(19) United States
(12) Patent Application Publication
(10) Pub. No.: US 2020/0127040 A1
(43) Pub. Date: Apr. 23, 2020

(54) Methods of Fabricating High Uniformity Semiconductor Films for Radiation Detection and Imaging

(71) Applicant: Dante D'Sant Angelo, Escondido, CA (US)

(72) Inventor: Dante D'Sant Angelo, Escondido, CA (US)

(21) Appl. No.: 16/583,219

(22) Filed: Sep. 25, 2019

Related U.S. Application Data
(60) Provisional application No. 62/736,999, filed on Sep. 26, 2018.

(51) Int. Cl. H01L 27/146; H01L 31/032; H01L 31/18; H01L 31/0224; H01L 31/0203; H01L 31/115; G01T 1/24

(52) U.S. Cl. CPC H01L 27/14683; H01L 31/032; H01L 31/1864; G01T 1/24; H01L 31/0203; H01L 31/115; H01L 27/14659; H01L 31/0224

(57) ABSTRACT

The subject innovation details a method, apparatus and process for a producing a uniform semiconductor film having excellent crystalline grain properties, wherein the uniform film with a consistent density and uniform crystalline orientation.

### PRIORITY CLAIM

This Application claims benefit and priority to U.S. Provisional Patent Application No. 62/736,999, filed on Sep. 26, 2018, the entirely of which is herein incorporated by reference.

### FIELD OF DISCLOSURE

This subject disclosure relates to the field of radiation/particle detection and imaging using solid state semiconductor materials, such as but not limited to, Thallium Bromide(TlBr), Lead Iodide(PbI₂) and Mercuric Iodide(HgI₂). More specifically this disclosure relates to the controlled growth of semiconductor detector films for flat panel X-ray imaging and detection. It is important to note that this disclosure is not restricted to X-ray imaging and maybe applied to other fields of electronics that may require one or more layer(s) of a polycrystalline semiconductor, such as photovoltaics for the conversion and storage of solar energy.

### BACKGROUND OF DISCLOSURE

Digital X-ray imaging generally consists of two basic detection methods: indirect and direct detection. In the indirect method, a scintillator layer such as Cesium Iodide(CsI:Tl) or Gadolinium Oxysulfide(Gadox) is deposited directly on top of a Thin Film Transistor(TFT) or Complementary Metal Oxide Semiconductor(CMOS) pixel array. These arrays are commonly comprised of a multitude of photosensitive pixels, each containing a photodetector, storage capacitor and a readout transistor or some combination of the like. In some cases, such as in certain CMOS arrays, more electronics maybe added to each pixel for amplification, signal processing and digitization. The scintillator absorbs the X-ray and converts it into visible light, this light is then sensed by each photosensitive pixel and converted into electrical charge. The indirect method, although efficient, is intrinsically limited in spatial resolution by the detection method, as it relies on a scintillator converting X-ray photons into visible light that may spread and fall on a group of pixels. As the converted light is detected by a group of pixels, this area may now be effectively counted as one larger pixel thus limiting the effective spatial resolution. An image of an indirect X-ray imaging system is provided in FIG. 1, wherein it is clearly detailed that the scintillator layer is bonded on top of a light sensing pixel array. The image also depicts that the scintillator layer converts X-ray photons into visible light photons and these visible photons, spread and fall onto multiple of the light sensing pixels.

The direct method of digital X-ray imaging involves the deposition or bonding of a semiconductor layer such as single crystal Cadmium Telluride (CdTe), Amorphous Selenium(a-Se) or polycrystalline materials such as Mercuric Iodide (HgI₂), Lead Iodide (PbI₂) or Thallium Bromide (TlBr), directly onto a TFT or CMOS pixel array. In this method, X-ray photons are converted directly into electron-hole pairs by the semiconductor material. These electron-hole pairs are then separated by an applied electrical field or “bias” into free electrons and holes and collected by the nearest pixel, as depicted in FIG. 2. As the electrons or holes are funneled into the pixel nearest to their origin, the intrinsic spatial resolution is much higher than in the indirect method.

Direct digital imaging, although effectively superior, is severally limited in commercial application due to high cost and difficulties in large area fabrication of said devices. Materials such as single crystal Cadmium Telluride (CdTe) are limited in practical size and require a complex and expensive bonding process. In this process the crystal is pixelated with metal pads and primed with micro solder bumps. The two substrates must then be aligned, pressed together and heated to form a stable electrical contact, see FIG. 3. Other potential materials such as Mercuric Iodide (HgI₂), Lead Iodide (PbI₂) or Thallium Bromide (TlBr) can be vapor deposited directly on the surface of a pixel array but suffer from issues such as severe non-uniformity, charge trapping and instability over time. This is largely due to an inability to control the structure of the crystalline grains, resulting in non-uniform films with random crystalline orientation, grain size and varying film density. As can be seen in FIG. 4, it is apparent that the HgI₂ semiconductor film is composed of disoriented polycrystalline grains, resulting in a jagged, non-uniform film surface. FIG. 5 further provides a detailed microscope image of an HgI₂ non-uniform semiconductor film.

### SUMMARY OF DISCLOSURE

The following description of exemplary embodiment(s) is merely illustrative in nature and is in no way intended to limit the invention, its application, or uses.

Processes, techniques, apparatus, and materials as known by one of ordinary skill in the relevant art may not be discussed in detail but are intended to be part of the enabling description where appropriate. For example, exemplary substrates and manufacturing methods may not be discussed in detail, however such substrates processes as known by one of ordinary skill in the art and equivalent methods, processes, and materials would fall within the intended scope of the subject application.

In one embodiment, the subject innovation teaches a radiation detection system, comprising a uniform semiconductor film formed by the process including printing a thin layer of nanoparticle ink and a carrier solvent directly on a substrate to create a seed layer, then burnishing the seed layer with a smooth tool to break down the semiconductor nanoparticles, followed by forming the nanoparticles into a thin high-density film having a grid that matches the pitch of the array; growing a thick film in the range of 50 μm-10001 μm from the prepared burnished thin film via Physical Vapor Deposition (PVD).

In other embodiments the radiation detection system includes nanoparticle inks which are selected from the group consisting of Mercuric Iodide (HgI₂), Lead Iodide (PbI₂) and Thallium Bromide (TlBr).

In yet another embodiment, the radiation detection system details the printing selected from the group consisting of ink jet printing, spray coating, doctor blading, spin coating, and other similar methods.

In other embodiment, the radiation detection system further teaches printing additional layers of nanoparticle ink printed upon each other to ensure no pinholes in the film.

The radiation detection system further comprising annealing the film, after burnishing, to sinter together the seed particles. In further incarnations, the radiation detection system incorporates the film oriented along the C-axis.

The radiation detection system further teaches the film being grown to a thickness of between 50-1000 μm via physical vapor deposition.

In yet additional embodiment, the radiation detection system further comprises etching the surface of the film after crystal growth via physical vapor deposition. Furthermore, the etching is selected from the group consisting of iodine water solution, potassium iodide, sodium iodide, lithium iodide, or various organic solvents such as acetone, tetrahydrofuran (THF), methyl ethyl ketone (MEK) or dimethyl sulfoxide (DMSO) and combinations therefrom.

In addition, the subject radiation detection system further comprising applying a conductive electrode to the film, and further encapsulating the film for protection.

In other embodiment, the subject innovation teaches a uniform semiconductor film having a substrate, and a thin layer of nanoparticle ink applied to the substrate to create a seed layer. Thereafter the seed layer is burnished with a smooth tool to pattern the semiconductor nanoparticles in a grid that matches the pitch of the array.

### BRIEF DESCRIPTION OF DRAWINGS

FIG. 1 is an illustration of an indirect X-ray imaging system as known in the prior art.

FIG. 2 is an illustration of a direct X-ray imaging system as known in the prior art.

FIG. 3 is an illustration of a direct X-ray imaging system fabricated by bonding a CdTe crystal to a pixel array with a solder bump bonding process as known in the prior art.

FIG. 4 is an illustration of an HgI₂ semiconductor film fabricated without a printed burnished seed layer, as known in the prior art.

FIG. 5 is an optical microscope image of an HgI₂ semiconductor film fabricated without a printed-burnished seed layer, as shown in FIG. 4.

FIG. 6 is a flow chart detailing the process steps involved in the fabricating of a high uniformity semiconductor film on various substrates, according to one or more elements of the subject innovation.

FIG. 7 is an illustration of a printed seed layer on a substrate surface, according to one or more elements of the subject innovation.

FIG. 8 is an illustration of a dense, burnished printed seed layer as a thin continuous film, according to one or more elements of the subject innovation.

FIG. 9 is an illustration of a hot-wall physical vapor deposition system for the crystal growth of semiconductor films, according to one or more elements of the subject innovation. It is shown that the chamber has heaters built around the walls and that the substrate holder is cooled by water flow allowing for the creation of a temperature differential between the substrate holder and the rest of the chamber.

FIG. 10 is an illustration of a finished device, consisting of a substrate, high uniformity semiconductor layer, metal layer and passivation, according to one or more elements of the subject innovation.

FIG. 11 is an optical microscope image of a high uniformity HgI₂ semiconductor film of FIG. 10, according to one or more elements of the subject innovation. It is noticeable that the grain boundaries run into each other and that the crystalline faces are all oriented and flat.

FIG. 12 is an illustration of a substrate being printed by a specialized ink jet printer head, according to one or more elements of the subject innovation.

FIG. 13 is an illustration of the nanoplatelet film morphology, according to one or more elements of the subject innovation.

FIG. 14 is an illustration of the burnishing process, wherein a smooth rounded tool is run across the nanoparticle film, compacting and breaking down the particles into a dense flat layer, according to one or more elements of the subject innovation.

FIG. 15 is an illustration of the morphology of a single nanoplatelet, according to one or more elements of the subject innovation.

FIG. 16 is a microscope image of a burnish patterned HgI₂ film, according to one or more elements of the subject innovation.

FIG. 17 is an illustration of a thermal evaporation system used to apply a top electrode to the grown HgI₂ film, according to one or more elements of the subject innovation.

FIG. 18 is an illustration of a parylene coating system used to hermetically seal the completed HgI₂ based device, according to one or more elements of the subject innovation.

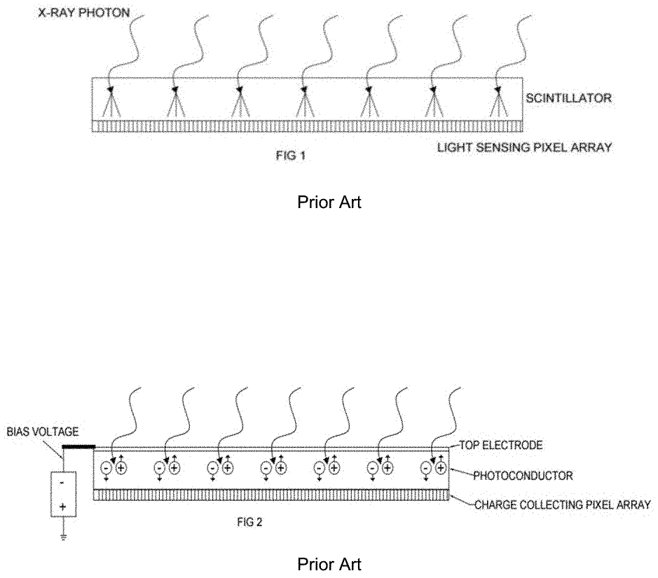

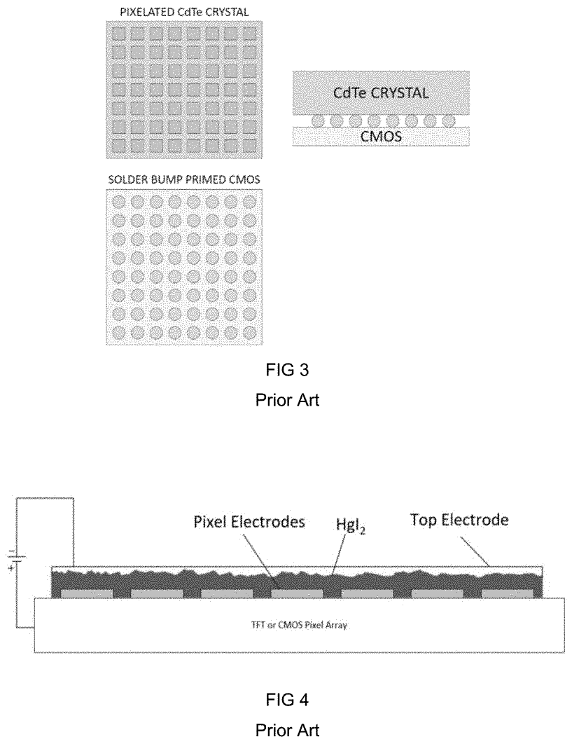

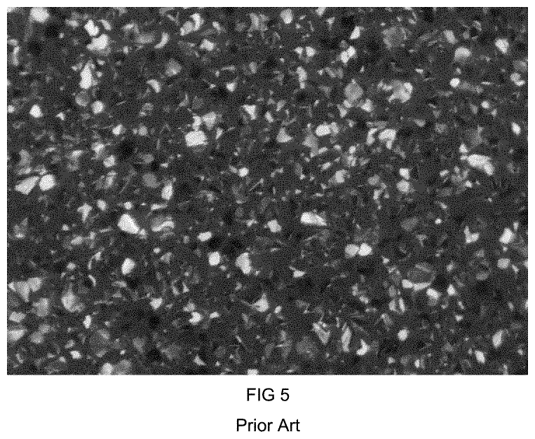

### DETAILED DISCLOSURE

The subject disclosure described herein is a method, product and process for fabricating uniform, oriented, vapor grown, polycrystalline films of 2D layered semiconductor materials, such as but not limited to HgI₂, PbI₂ and TlBr, on CMOS, TFT, PCB, glass, ceramic based pixel arrays or unpatterned substrates for radiation detection and imaging. The resulting crystalline structure allows for optimized physical properties and approaches the performance attributes of a single crystal.

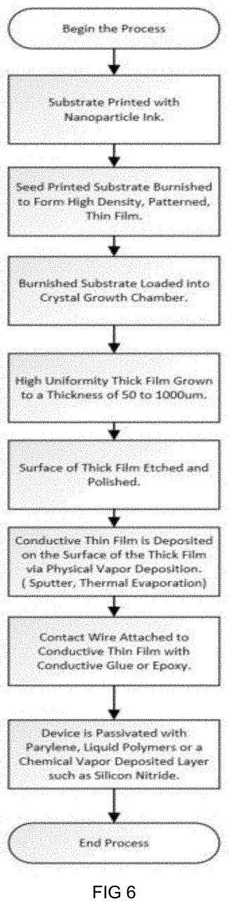

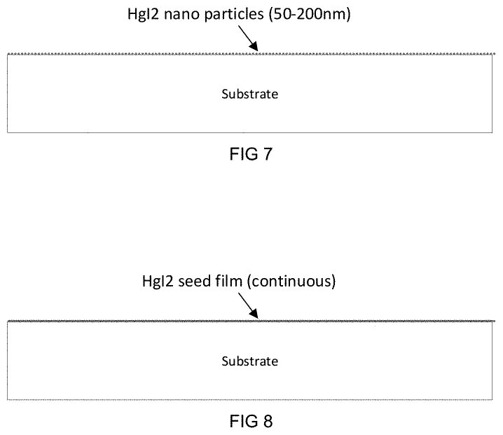

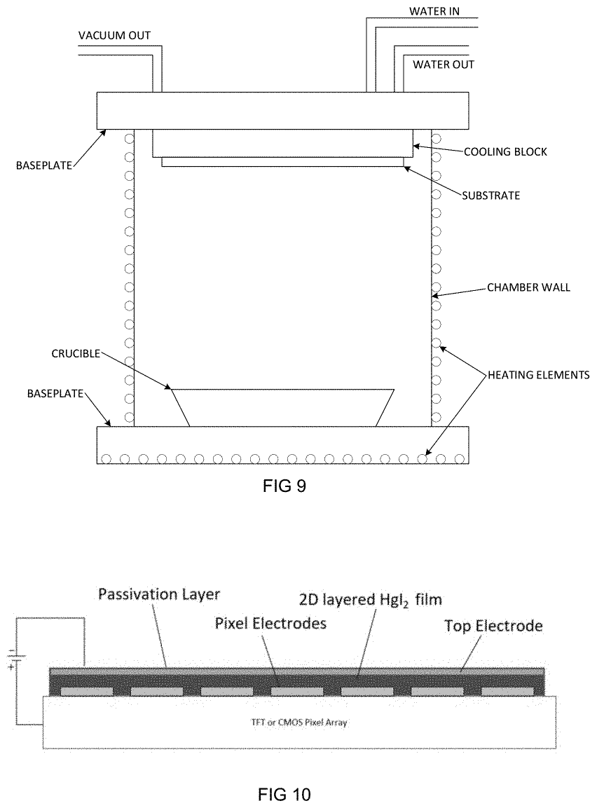

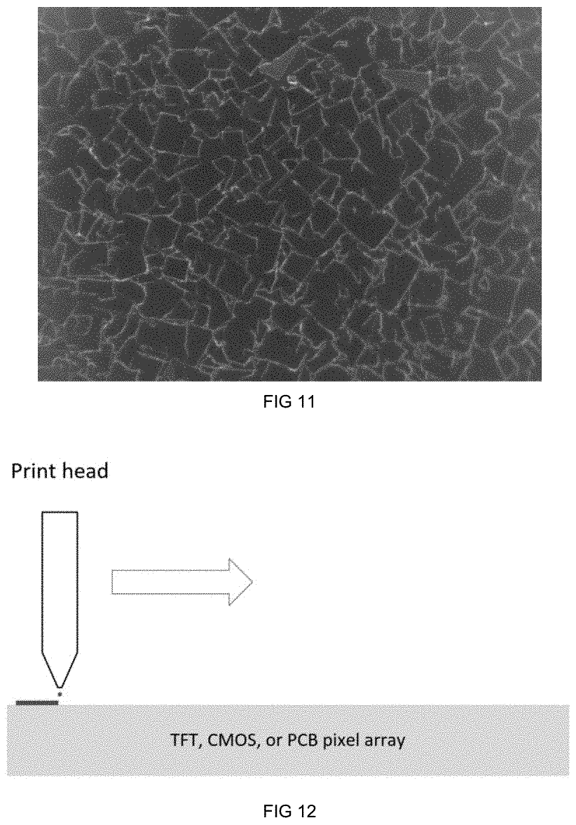

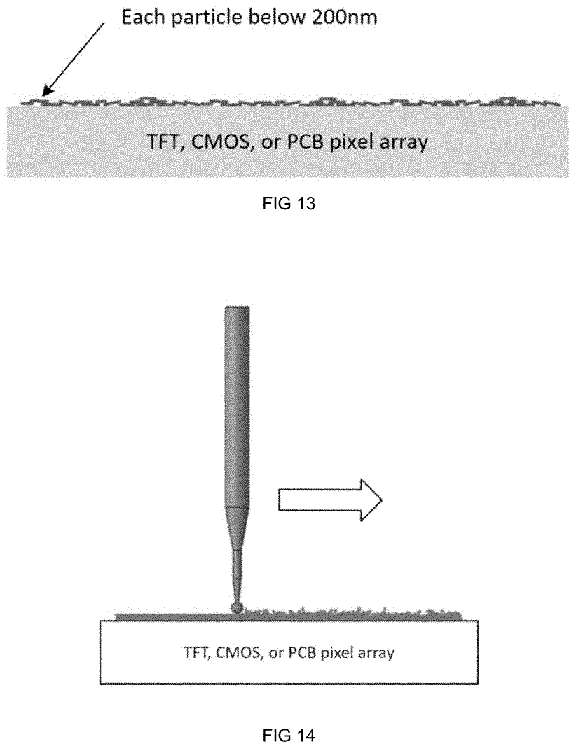

As provided in the flow chart of FIG. 6, this is achieved by printing a thin layer of nanoparticle ink 14 composed of the intended material (e.g. HgI₂, PbI₂ and TlBr) suspended in a carrier solvent 16, directly on the surface of the desired substrate 18 via ink jet printing, spray coating, doctor blading, spin coating, or other similar deposition methods. Various appropriate carrier solvents 16 may include alcohols, ketones, aldehydes and glycol ethers or hydrocarbons solvents such as toluene, hexane and xylene. This printing step leaves a thin layer of nanoparticle ink film 20 or “seeds” with a high level of feature accuracy on the substrate 18, an example of this is depicted in FIG. 7. Please note, that FIG. 10 exaggerates the spacing between the nanoparticle ink 14 deposited on the surface of the substrate 18, to better depict the delta. The “seed” printed substrate 18 may then be supplanted with additional layers of nanoparticle ink 14 printed upon each other in multitude to ensure no pinholes in the film, adding to the film 20.

The film 20 must then be burnished by a smooth tool 22 with a rounded edge 24 constructed from materials with a low coefficient of friction such as Polytetrafluoroethylene (PTFE), or highly polished materials such as agate, quartz or ruby, as represented in FIG. 14. This step breaks down the semiconductor nanoparticles film 20, forming it into a thin high-density thin film 20. In the case of materials such as HgI₂, that are composed of 2-dimensional planes held together by Van der Waals force, burnishing delaminates the planes of the material, resulting in a film 20 of uniform orientation. Additionally, by carefully controlling the burnishing tool 22 and technique, it is possible to pattern the film 20 with a grid that matches the pitch of the array, resulting in a single crystal column for each pixel in the array.

Optionally, the film 20 may then be high temperature annealed to sinter together the seed particles into a denser, more cohesive mass. For materials that are temperature sensitive, solvent annealing maybe employed. The solvent annealing involves placing the film 20 printed substrate 18 into a closed chamber saturated with an applicable solvent. Suitable choices are volatile solvents that have good solubility with the target material. This exposure causes a partial solvation of the film 20 particles, effectively fusing them into single mass.

After the optional annealing, the substrate 18 may then be loaded into a crystal growth chamber, also known as a Physical Vapor Deposition (PVD) chamber 30, displayed in FIG. 9. During this process, a “source” material 34 (HgI₂, PbI₂, TlBr) is placed in a chamber 30 with the treated substrate 32 oriented directly over it. The chamber 30 is then pumped down to high vacuum level (<1×10⁻⁵ torr) and the source material is heated using heating elements 36 till it begins to vaporize. As the liberated vapor travels toward the substrate 32, it impinges on the film 20 and coalesces into a crystalline solid, using the film 20 as a template for growth. Due to the prior treatment of the film 20, produced by the printing and burnishing technique, all growth potential is nearly equal across the substrate 32, resulting in growth that is uniform and conducted with exclusive orientation. This flat and oriented film 20 may be grown to a practical thickness of 50 μm-1000 μm. The resulting oriented thick film 20 can then be removed from the chamber for further processing. A cooling block 38 may be used to cool the finished thick film 20 prior to removal, ensuring crystalline structure.

Additional steps may include etching the surface of the film 20 with an iodide/water solution of either potassium iodide, sodium iodide, lithium iodide or other suitable compounds. It is also possible to use other etchants such as various organic solvents such as acetone, tetrahydrofuran (THF), methyl ethyl ketone (MEK) or dimethyl sulfoxide (DMSO).

As provided in FIG. 10, a conductive top electrode layer 40 may then be applied to the film 20 by deposition of a metal layer of either platinum, palladium, nickel, molybdenum, ruthenium, chromium, indium tin oxide or other compatible metals/conductors, through vapor deposition methods such as thermal evaporation and sputtering or liquid based deposition of colloidal suspensions or solutions via ink jet printing, spray coating, doctor blading or spin coating. A lead wire 42 must then be attached to the conductive film 20 for bias voltage application. The lead wire 42 may be adhered to the electrode using conductive glues consisting of electrically conductive particles of carbon, silver, copper and nickel dispersed in a polymer or epoxy. After lead wire attachment, the device can then be encapsulated in a thin passivation layer 44 of a vapor deposited polymer known as parylene. Other encapsulants maybe used such as plasma polymers, or solvent based polymer coatings such as Humiseal or acrylic mixtures. Additionally, encapsulants may be applied through chemical vapor deposition (CVD) such as but not limited to silicon nitride (SiN) or silicon dioxide (SiO₂). Encapsulants may also be applied in succession or as a mixture for greater chemical and mechanical stability.

In this embodiment of the disclosure, see FIG. 6, a layer of Mercuric Iodide is formed on a CMOS, TFT, PCB, glass or ceramic based pixel array. This is accomplished by inkjet printing a thin layer of specialized HgI₂ ink onto the surface on the substrate. The ink itself is composed of HgI₂ nano-platelets (200 nm≥) oriented with the C-planes being the dominant surface and dispersed in a carrier solvent, such as methanol.

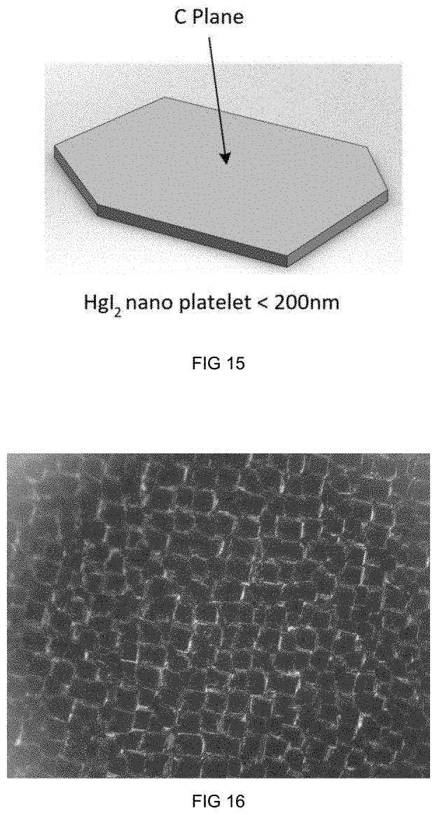

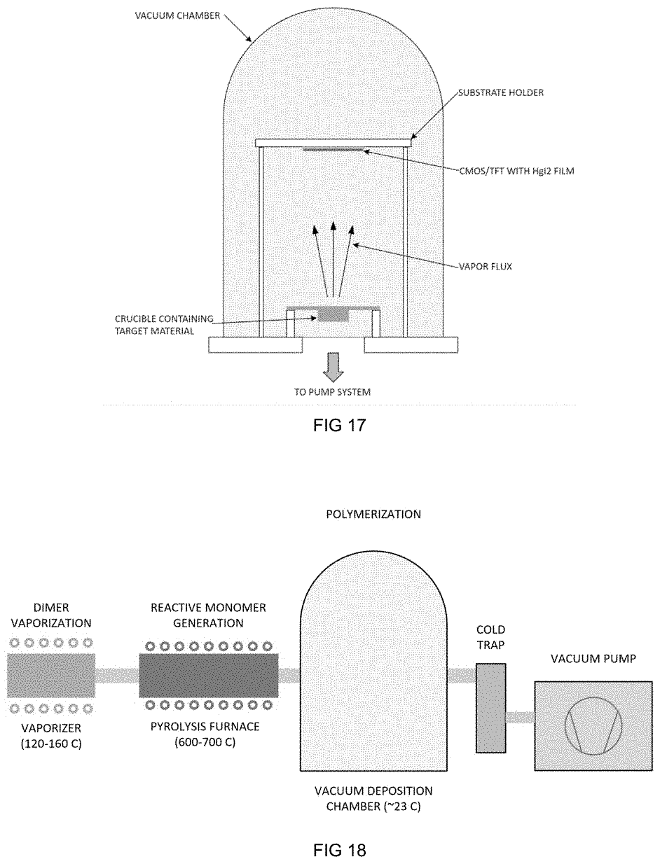

Due to the platelet shape of the nanoparticles seen in FIG. 15, the printed layer is comprised of generally aligned flat planes stacked on top of each other. After printing is accomplished, the films 20 may then be burnished using a smooth Teflon tool 22 as seen in FIG. 14. The result is a thin film, pre-oriented with the C-axis perpendicular to the substrate, as depicted in FIG. 8. The “primed” substrate can then be loaded into a special physical vapor deposition 30 reactor for growth of the active semiconductor layer up to 1000 μm in thickness. The grown thick film 20 may then be contacted with a palladium film in a thermal evaporator 46 as seen in FIG. 17. This palladium film acts as the top electrode of the device and is used to apply a bias voltage. A thin palladium lead wire 42 may then be attached to the palladium contact electrode using conductive carbon glue. The device may then be placed in a parylene coater for passivation. During this process a thin layer of a vapor deposited plastic known as parylene is applied to the device for a hermetic seal, such a system is depicted in FIG. 18.

1. A radiation detection system, comprising a uniform semiconductor film formed by process comprising:
printing a thin layer of nanoparticle ink and a carrier solvent directly on a substrate to create a seed layer;
burnishing the seed layer with a smooth tool to break down the semiconductor nanoparticles; and
forming the nanoparticles into a thin high-density film having a grid that matches the pitch of the array; growing a thick film in the range of 50 μm-1000 μm from the prepared burnished thin film via Physical Vapor Deposition (PVD).

2. The radiation detection system according to claim 1, wherein the nanoparticle ink is selected from the group consisting of Mercuric Iodide (HgI₂), Lead Iodide (PbI₂) and Thallium Bromide (TlBr).

3. The radiation detection system according to claim 1, wherein the printing is selected from the group consisting of ink jet printing, spray coating, doctor blading, spin coating, and other similar methods.

4. The radiation detection system according to claim 1, further comprising printing additional layers of nanoparticle ink printed upon each other to ensure no pinholes in the film.

5. The radiation detection system according to claim 1, further comprising annealing the film, after burnishing, to sinter together the seed particles.

6. The radiation detection system according to claim 1, wherein the film is oriented along the C-axis.

7. The radiation detection system according to claim 1, wherein the film is grown to a thickness of between 50-1000 μm via physical vapor deposition.

8. The radiation detection system according to claim 1, further comprising etching the surface of the film after crystal growth via physical vapor deposition.

9. The radiation detection system according to claim 8, wherein the etching is selected from the group consisting of iodine water solution, potassium iodide, sodium iodide, lithium iodide, or various organic solvents such as acetone, tetrahydrofuran (THF), methyl ethyl ketone (MEK) or dimethyl sulfoxide (DMSO) and combinations therefrom.

10. The radiation detection system according to claim 1, further comprising applying a conductive electrode to the film.

11. The radiation detection system according to claim 1, further comprising encapsulating the film for protection.

12. A uniform semiconductor film comprising:
a substrate; and
a thin layer of nanoparticle ink applied to the substrate to create a seed layer;
wherein the seed layer is burnished with a smooth tool to pattern the semiconductor nanoparticles in a grid that matches the pitch of the array.

13. The semiconductor film according to claim 12, wherein the nanoparticle ink is selected from the group consisting of Mercuric Iodide (HgI₂), Lead Iodide (PbI₂) and Thallium Bromide (TlBr).

14. The semiconductor film according to claim 12, wherein the applying the ink to the substrate is selected from the group consisting of ink jet printing, spray coating, doctor blading, spin coating, and other similar methods.

15. The semiconductor film according to claim 12, further comprising applying additional layers of nanoparticle ink upon each other to ensure no pinholes in the film.

16. The semiconductor film according to claim 12, further comprising sintering the seed particles together by an annealing process.

17. The semiconductor film according to claim 12, wherein the film is oriented in the C-axis.

18. The semiconductor film according to claim 12, wherein the film has a thickness of between about 50-1000 μm.

19. The radiation detection system according to claim 12, further comprising an etching solution selected from the group consisting of iodine water solution, potassium iodide solution, sodium iodide solution, lithium iodide solution, acetone, THF, MEK, DMSO and combinations therefrom, for etching the film.

20. The radiation detection system according to claim 12, further comprising applying a conductive electrode to the film.
